(19) United States
(12) Patent Application Publication
(10) Pub. No.: US 2025/0098098 A1
(43) Pub. Date: Mar. 20, 2025

(54) POWER CONVERSION APPARATUS

(71) Applicant: FUJI ELECTRIC CO., LTD., Kawasaki-shi (JP)

(72) Inventor: Takanori SHINTANI, Suzuka-shi (JP)

(21) Appl. No.: 18/783,426

(22) Filed: Jul. 25, 2024

(30) Foreign Application Priority Data
Sep. 20, 2023 (JP) 2023-152228

(51) Int. Cl. H05K 7/14; H02M 1/00; H02M 1/32; H02M 7/00

(52) U.S. Cl. CPC H05K 7/14329; H02M 1/0009; H02M 1/007; H02M 7/003; H02M 1/008; H02M 1/327

(57) ABSTRACT

A power conversion apparatus includes a direct current/direct current converter, an inverter, a boost converter, a current sensor for measuring a current that flows through the boost converter, and a base, wherein the current sensor includes a sensing part for measuring the current flowing through the boost converter, and a housing having a single fastening through hole through which a fastener is inserted to fasten the current sensor to the base and a positioning through hole for positioning the current sensor with respect to the base.

### CROSS-REFERENCE TO RELATED APPLICATIONS

The present application is based on, and claims priority from a Japanese Patent application number JP 2023-152228 filed on Sep. 20, 2023, the disclosure of which is hereby incorporated by reference herein in its entirety.

### BACKGROUND

### Technical Field

The present disclosure relates to a power conversion apparatus, and to a power conversion apparatus including a boost converter, an inverter, and a direct current/direct current converter.

### Description of the Background Art

Power conversion apparatuses including a boost converter, an inverter, and a direct current/direct current or DC/DC converter are known in the art. Such a power conversion apparatus is disclosed in Japanese Patent Laid-Open Publication No. JP2023-53944, for example.

The power conversion apparatus disclosed in Japanese Patent Laid-Open Publication No. JP2023-53944 includes a boost converter, an inverter, and a direct current/direct current converter. In a configuration disclosed in the above Patent Document 1, the direct current/direct current converter and the inverter are arranged at positions facing each other. Also, the above Patent Document 1 discloses a configuration in which the boost converter boosts direct current electric power input from a direct current power supply, and supplies the electric power boosted to the inverter unit.

Although not stated in Japanese Patent Laid-Open Publication No. JP2023-53944, power conversion apparatuses generally have a current sensor for measuring a current flowing through the boost converter. In a case in which such a current sensor is provided to the power conversion apparatus disclosed in the above Patent Document 1, it is desired to suppress increase of the number of parts and to reduce a burden in assembling work.

### SUMMARY

The present disclosure is intended to solve the above problem, and one object of one or more embodiments of the present invention, for example, is to provide a power conversion apparatus capable of suppressing increase of the number of parts and reducing a burden in assembling work.

In order to attain the aforementioned object, a power conversion apparatus according to one aspect of the present invention includes a boost converter for boosting direct current power input from a direct current power supply; an inverter for converting the direct current power boosted by the boost converter into alternate current power and to supply the alternate current converted to a load; a direct current/direct current or DC/DC converter for boosting the direct current power input from the direct current power supply; a current sensor for measuring a current that flows through the boost converter; and a flat-plate-shape base to which the boost converter, the inverter, the direct current/direct current converter, and the current sensor are arranged, wherein the current sensor includes a sensing part for measuring the current flowing through the boost converter, and a housing having a single fastening through hole through which a fastener is inserted to fasten the current sensor to the base and a positioning through hole for positioning the current sensor with respect to the base.

In the power conversion apparatus according to the aforementioned one aspect of this invention, as discussed above, the current sensor includes a housing having a single fastening through hole through which a fastener is inserted to fasten the current sensor to the base, and a positioning through hole for positioning the current sensor with respect to the base. According to this configuration, dissimilar to a configuration in which the housing is fastened by a plurality of fasteners, because the housing can be fastened to the base by fastening a single fastener, it is possible to suppress increase of the number of parts. Also, because the housing has the positioning through hole, it is possible to easily position the housing by using the positioning through hole when the housing is fixed to the base. Also, because the housing can be fixed to the base by fastening a single fastener, as compared with a case in which the housing is fixed to the base by fastening a plurality of fasteners, it is possible to reduce a burden in assembling work. Consequently, it is possible to suppress increase of the number of parts and to reduce a burden in assembling work.

In the power conversion apparatus according to the aforementioned aspect, the housing may include a first protruding part protruding from one side surface of a pair of first side surfaces facing each other, and a second protruding part protruding from another side surface of the pair of first side surfaces; that the fastening through hole is positioned in the first protruding part; and that the positioning through hole includes/include a first positioning through hole provided in the second protruding part. According to this configuration, because the first protruding part and the second protruding part protrude from different side surfaces of the pair of first side surfaces, the fastening through hole and the first positioning through hole can be provided in different side surfaces of the pair of first side surfaces. For this reason, as compared with a configuration in which the fastening through hole and the first positioning through hole are provided on a common side surface of the pair of first side surfaces, the fastening through hole and the first positioning through hole can be arranged at positions spaced further away from each other. Also, because the fastener inserted into the fastening through hole also facilitates to position the housing, as compared with the configuration in which the fastening through hole and the first positioning through hole are provided on the common side surface of the pair of first side surfaces, the housing can be positioned by using two positions spaced further away from each other. For this reason, it is possible to accurately position the housing when the housing is fixed by the fastener. Consequently, as compared with the configuration in which the fastening through hole and the first positioning through hole are provided on the common side surface of the pair of first side surfaces, it is possible to improve positioning accuracy of the current sensor.

In this configuration, the positioning through holes may further include a second positioning through hole provided in the first protruding part for positioning the current sensor with respect to the base. According to this configuration, because the current sensor can be positioned by using two positioning through holes, which are the first positioning through hole and the second positioning through hole, as compared with a case in which only one positioning through hole is provided, it is possible to easily and reliably position the current sensor.

In the aforementioned configuration in which the positioning through holes include the second positioning through hole, the first positioning through hole may have an elongated hole shape extending in a first direction in which the first protruding part and the second protruding part are aligned; and that the second positioning through hole has a round shape. According to this configuration, because the first positioning through hole has an elongated hole shape extending in the first direction, it is possible to absorb manufacturing errors of the housing and the base in the first direction. In addition, because the first positioning through hole has an elongated hole shape extending in the first direction, it is possible to position the housing with respect to the base in a direction intersecting the first direction while absorbing manufacturing errors of the housing and the base in the first direction. Consequently, the current sensor can be easily positioned by positioning the housing with respect to the second positioning through hole, which has a round shape, even if the housing and the base have manufacturing errors in the first direction.

In the aforementioned configuration in which the fastening through hole is positioned in the first protruding part, and the positioning through hole includes/include a first positioning through hole provided in the second protruding part, the housing may have a first end surface on the base side, and a second end surface opposite to the first end surface; and that the first protruding part and the second protruding part are arranged on the pair of the first side surfaces on the first end surface side to form stepped parts between the second end surface, and the first protruding part and the second protruding part. Here, for example, in a case in which the current sensor is fixed to the base without being in contact with the base, the housing is fixed to a boss that is formed on the base and has an engagement part with which the fastener engages. Also, bosses that have protrusions to be inserted into the positioning through holes are formed on the base to position the housing when positioning the housing. If the boss that has the engagement part, and the bosses that have the protrusions to be inserted into the positioning through holes have large heights, a material amount of the base increases. To address this, according to this configuration, it is possible to arrange the fastening through hole and the positioning through holes closer to the base as compared with a configuration in which the fastening through hole and the positioning through holes are arranged coplanar with the second end surface. For this reason, it is possible to reduce the heights of the boss that has the engagement part for the fastener for fastening the current sensor to the base, and the bosses that have the protrusions to be inserted into the positioning through holes and to position the current sensor. Consequently, it is possible to reduce a material amount of the base as compared with the configuration in which the fastening through hole and the positioning through holes are arranged coplanar with the second end surface.

In this configuration, an end surface of the first protruding part on the base side, and an end surface of the second protruding part on the base side may be located on the second end surface side with respect to a center between the first end surface and the second end surface. Here, in a case in which the first protruding part and the second protruding part are located closer to the first end surface, the first protruding part and the second protruding part are located at far places from a viewpoint of a worker when the worker attaches the current sensor to the base. For this reason, as compared with a case in which the first protruding part and the second protruding part are located at places closer from a viewpoint of the worker, the worker cannot easily see position of the first positioning through hole when inserting the positioning protrusion into the first positioning through hole formed in the second protruding part. In addition, the worker cannot easily see position of the fastening through hole when inserting the fastener into the fastening through hole formed in the first protruding part. Contrary to this, according to this configuration, the positions of the first protruding part and the second protruding part can be closer to the second end surface side while stepped parts can be formed between the first protruding part and the second protruding part, and the second end surface. Accordingly, the fastening through hole and the first positioning through hole can be located closer to the second end surface. As a result, the worker can easily see position of the first positioning through hole when positioning the current sensor. In addition, the worker can easily see position of the fastening through hole when fixing the current sensor to the base. Consequently, the worker can easily position and fasten the current sensor while a material amount of the base is reduced.

In the aforementioned configuration in which the fastening through hole is positioned in the first protruding part, and the positioning through hole includes/include a first positioning through hole provided in the second protruding part, the first protruding part may have the fastening through hole formed at a position aligned, in a first direction in which the first protruding part and the second protruding part are aligned, with a central part of the pair of first side surfaces in a second direction intersecting the first direction; and that the second protruding part has the first positioning through hole formed at a position aligned, in the first direction with, a central part of the pair of first side surfaces. According to this configuration, a fastening force can be applied to a central part of the housing in the second direction when the current sensor is fixed to the base. As a result, because the fastening force can be evenly applied to one end side and another end side of the housing in the second direction, it is possible to stably fix the current sensor to the base as compared with a configuration in which the fastening through hole is arranged in a part on one of the end sides in the second direction.

In the power conversion apparatus according to the aforementioned aspect, the current sensor may further include a pair of busbars one of which is connected to the boost converter; and that the pair of busbars is provided on a pair of second side surfaces, which are different from the pair of first side surfaces. According to this configuration, because the pair of busbars is provided on the pair of second side surfaces, which are different from the pair of first side surfaces, the pair of busbars can be prevented from interfering with positioning and fastening work when the current sensor is positioned and fastened as compared to a configuration in which the pair of busbars is provided on the pair of first side surfaces. Consequently, it is possible to improve workability of positioning and fastening the current sensor.

The foregoing and other objects, features, aspects and advantages of the present invention will become more apparent from the following detailed description when taken in conjunction with the accompanying drawings.

### BRIEF DESCRIPTION OF THE DRAWINGS

FIG. 1 is a circuit diagram of a power conversion apparatus according to one embodiment.

FIG. 2 is a perspective view of the power conversion apparatus according to the one embodiment.

FIG. 3 is a side view of the power conversion apparatus according to the one embodiment.

FIG. 4 is an exploded view illustrating a configuration of a current sensor, and an attachment configuration in which the current sensor is attached to a base according to the one embodiment.

FIG. 5 is a side view of the current sensor according to the one embodiment.

FIG. 6 is a top view of the current sensor according to the one embodiment.

### DESCRIPTION OF THE EMBODIMENTS

Embodiments embodying the present invention will be described with reference to the drawings.

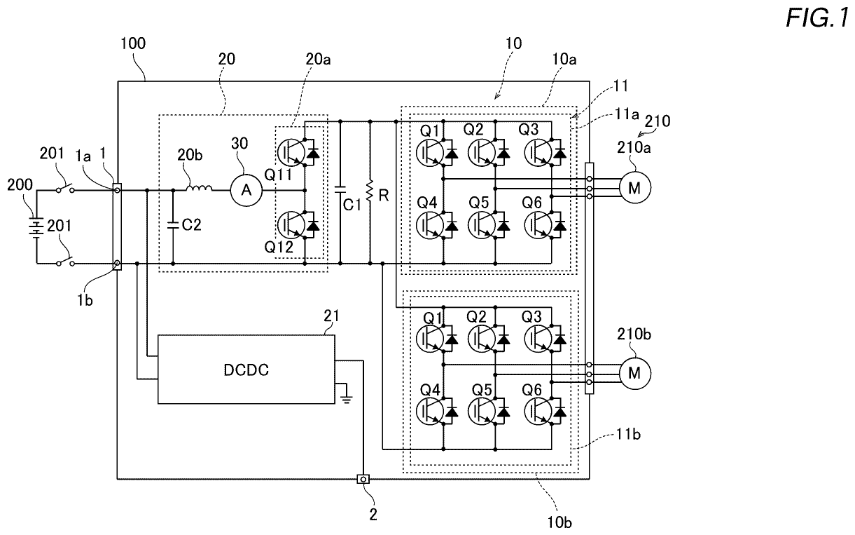

A configuration of a power conversion apparatus 100 according to one embodiment of the present invention will be described with reference to FIGS. 1 to 6. The power conversion apparatus 100, for example, is installed on a vehicle.

A circuit configuration of the power conversion apparatus 100 is first described with reference to FIG. 1. The power conversion apparatus 100 includes input terminals 1 and an output terminal 2. The power conversion apparatus 100 includes of an inverter 10, a boost converter 20, a direct current/direct current converter 21, a current sensor 30, and a direct current power supply 200. Also, the power conversion apparatus 100 includes a capacitor C1 and a resistor R.

The inverter 10 converts direct current power boosted by the boost converter 20 into alternate current power, and supplies the alternate current converted to loads 210. The loads 210 are electric motors, for example. Switches 201 are connected between the power conversion apparatus 100 and the direct current power supply 200.

The inverter 10 includes switching element modules 11. The switching element modules 11 convert direct current power into alternating current power. Each switching element module 11 includes semiconductor switching elements Q1, Q2 and Q3 that construct an upper arm, and semiconductor switching elements Q4, Q5 and Q6 that construct a lower arm.

The inverter 10 includes a first inverter 10a and a second inverter 10b. Switching element modules 11 include a first switching element module 11a included in the first inverter 10a, and a second switching element module 11b included in the second inverter 10b. Also, the loads 210 include a first load 210a and a second load 210b. The first inverter 10a converts the direct current power input from the direct current power supply 200 into alternate current power, and supplies the alternate current power to the first load 210a. The second inverter 10b converts the direct current power input from the direct current power supply 200 into alternate current power, and supplies the alternate current power to the second load 210b.

The boost converter 20 boosts the direct current power input from the direct current power supply 200. In this embodiment, the boost converter 20 supplies the direct current power boosted to the inverter 10. That is, the boost converter 20 is connected on an input side of the inverter 10. The boost converter 20 includes a boost switching element module 20a, and a reactor 20b. The boost switching element module 20a includes boost switching elements Q11 and Q12. The boost switching elements Q11 and Q12 construct the upper and lower arms, respectively. In addition, the boost converter 20 includes a capacitor C2.

The reactor 20b is connected between a positive side of the direct current power supply 200, and a connection point between the boost switching element Q11 and the boost switching element Q12. The capacitor C1 is connected between the boost converter 20 and the inverter 10. In this embodiment, the resistor R is connected between the boost converter 20 and the inverter 10. The capacitor C1 and the resistor R are connected in parallel to each other. Also, the capacitor C2 is connected in parallel to the boost switching element Q12.

The converter 21 boosts direct current power input from the direct current power supply 200. In this embodiment, the direct current/direct current converter 21 converts a voltage of the direct current power into a different voltage. Specifically, the direct current/direct current converter 21 reduces the voltage of the direct current power input from the direct current power supply 200 through the input terminals 1. The direct current/direct current converter 21 supplies the reduced voltage to the output terminal 2.

The current sensor 30 measures a current that flows through the boost converter 20. In this embodiment, the current sensor 30 is connected between the reactor 20b and the boost switching element module 20a. That is, the current sensor 30 is configured to measure the current that flows through the reactor 20b.

The capacitor C1 is connected between the boost converter 20 and the inverter 10. In this embodiment, the resistor R is connected between the boost converter 20 and the inverter 10. The capacitor C1 and the resistor R are connected in parallel to each other.

The direct current power supply 200 includes the input terminal 1 connected to the inverter 10 side. The input terminals 1 include a positive terminal 1a and a negative terminal 1b.

Direct current power that is stepped down by the direct current/direct current converter 21 is output through the output terminal 2. The output terminal 2 is connected to a controller (not shown), or the like.

A structure of the power conversion apparatus 100 is now described.

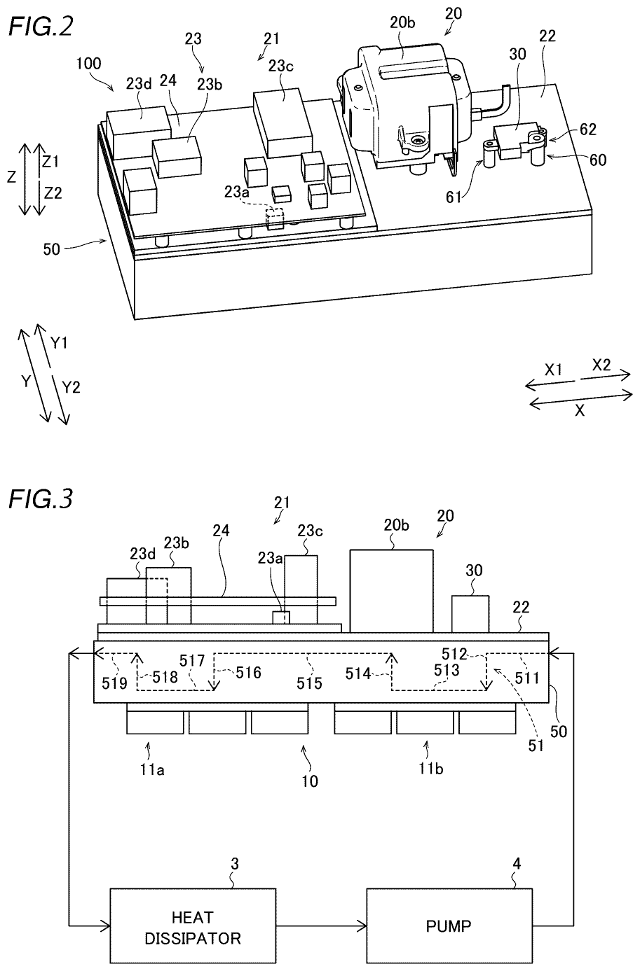

In this embodiment, as shown in FIG. 2, the power conversion apparatus 100 includes a flat-plate-like base 22 on or above which the boost converter 20, the inverter 10 (see FIG. 1), the direct current/direct current converter 21, and the current sensor 30 are arranged. In this embodiment, the current sensor 30 is installed through a first boss 60, a second boss 61, and a third boss 62 onto the base 22. The first boss 60, the second boss 61, and the third boss 62 are integrally formed with the base 22. Alternatively, the first boss 60, the second boss 61, and the third boss 62 can be separately formed from the base 22 and be fixed to the base 22. Note that the boost switching element module 20a (see FIG. 1) is omitted in an exemplary arrangement shown in FIG. 2 for ease of illustration.

In this embodiment, as shown in FIG. 2, the direct current/direct current converter 21 includes direct current/direct current converter elements 23, and a direct current/direct current converter board 24 on which the direct current/direct current converter elements 23 is mounted. The direct current/direct current converter board 24 has a flat plate-like shape. The direct current/direct current converter board 24 is arranged above the base 22. The direct current/direct current converter elements 23 mounted on the direct current/direct current converter board 24 includes a converter switching element 23a, a transformer 23b, a resonant reactor 23c, and a smoothing reactor 23d.

In this specification, a frontward/backward direction of the base 22 is defined as a Z direction. A direction from a back side toward a front side of the base 22 is defined as a Z1 direction, while a direction from the front side toward the back side of the base 22 is defined as a Z2 direction in the Z direction. One of two directions orthogonal to the Z direction and to each other is defined as an X direction, and another direction is defined as a Y direction. One direction is defined as an X1 direction, and another direction is defined as an X2 direction in the X direction. One direction is defined as a Y1 direction, and another direction is defined as a Y2 direction in the Y direction.

The converter switching element 23a is installed on a part on the back side (Z2 direction side) with respect to the direct current/direct current converter board 24. The transformer 23b, the resonant reactor 23c and the smoothing reactor 23d are arranged to pass through the direct current/direct current converter board 24.

Also, as shown in FIG. 2, the power conversion apparatus 100 includes a cooler 50. The cooler 50 has a flat plate-like shape. The cooler 50 is arranged between the inverter 10 (see FIG. 1) and the direct current/direct current converter 21. Also, the cooler 50 is formed of a metal having a relatively high thermal conductivity, such as aluminum, for example. The cooler 50 has a rectangular shape as viewed in a direction orthogonal to a front surface (a surface on the front side (a surface on the Z1 side)) and a back surface (a surface on the back side (a surface on the Z2 side)) of the cooler 50. The cooler 50 includes a cooling flow path 51 (see FIG. 3) through which a cooling liquid flows. In the structure illustratively shown in FIG. 2, the power conversion apparatus 100 is illustrated so that a longitudinal direction of the cooler 50 extends in the X direction, and a shorter direction extends in the Y direction.

In this embodiment, the switching element modules 11 of the inverter 10 (see FIG. 3) are mounted to the cooler 50 so as to extend along the front surface or the back surface of the flat-plate-like cooler 50. Also, the direct current/direct current converter board 24 on which the direct current/direct current converter elements 23 are mounted to the cooler 50 so as to extend along the front surface or the back surface of the flat-plate-like cooler 50.

Specifically, in this embodiment, the switching element modules 11 are mounted to the cooler 50 so as to extend along the back surface of the flat-plate-like cooler 50. That is, the inverter 10 is arranged on the another direction side (Z2 direction side) of the cooler 50. The direct current/direct current converter board 24 on which the direct current/direct current converter elements 23 are mounted are mounted to the cooler 50 so as to extend along the front surface of the flat-plate-like cooler 50.

In this embodiment, the boost converter 20 is mounted to the cooler 50 so as to extend along the front surface or the back surface of the flat-plate-like cooler 50. Specifically, the boost converter 20 is mounted to the front surface of the cooler 50. The boost converter 20 is arranged adjacent to the direct current/direct current converter 21 so as to extend in the longitudinal direction (X direction) of the flat-plate-like cooler 50.

As shown in FIG. 3, the cooling flow path 51 is formed so that the cooling liquid alternately passes through the front surface and the back surface of the cooler 50. Specifically, the cooling flow path 51 includes cooling flow paths 511, 515 and 519, which are arranged on the front side (front surface side) as front side flow paths, cooling flow paths 513 and 517, which are arranged on the back side (back surface side) as back side flow paths, and cooling flow paths 512, 514, 516 and 518 as connecting flow paths. The cooling flow path 51 is formed so that the cooling liquid flows into one end of the cooler 50 in the longitudinal (X direction), and the cooling liquid flows out from another end.

The cooling flow paths 511, 512, 513, 514, 515, 516, 517, 518 and 519 in the cooling flow path 51 are connected to each other in this order from an upstream side toward a downstream side. In other words, as shown in FIG. 3, in the cooling flow path 51, the cooling liquid flows into the cooling flow path 511 as the front side flow path through the cooling flow path 512 as the connecting flow path, the cooling flow path 513 as the back side flow path, the cooling flow path 514 as the connecting flow path, the cooling flow path 515 as the front side flow path, the cooling flow path 516 as the connecting flow path, the cooling flow path 517 as the back side flow path and the cooling flow path 518 as the connecting flow path, and then flows out through the cooling flow path 519 as the front side flow path. Alternatively, an inlet through which the cooling liquid flows into the cooling flow path 51 and an outlet through which the cooling liquid flows out of the cooling flow path can be arranged in a central part of the cooler 50 in the shorter direction. According to this arrangement, because positions of the inlet through which the cooling liquid flows into the cooling flow path and the outlet through which the cooling liquid flows out of the cooling flow path are unchanged irrespective of whether the surface on which the direct current/direct current converter 21 is arranged is an upper surface or a lower surface when the power conversion apparatus 100 shown in FIG. 2 is accommodated in customer's machine, the customer does not necessarily change a cooling liquid piping arrangement.

Also, the cooling liquid that flows out of the cooling flow path 51 is cooled by dissipating its heat by using a heat dissipator 3. Also, the cooling liquid that is cooled by the heat dissipator 3 is fed by a pump 4, and flows back into the cooling flow path 51. The heat dissipator 3 includes a heat exchanger to be cooled by outside air. The heat dissipator 3 is a radiator, for example. Alternatively, the pump 4 can be connected between the outlet of the cooling flow path 51 and the heat dissipator 3 so that the cooling liquid before the heat dissipation by the heat dissipator 3 is fed by the pump 4. For example, the cooling liquid is water, antifreeze, or the like.

Also, as shown in FIG. 3, the inverter 10 is arranged on the back surface of the cooler 50. That is, the inverter 10 is arranged on the another direction side (Z2 direction side) of the cooler 50. The inverter 10 is cooled by the cooling liquid flowing through the back side flow paths (cooling flow path 513 and cooling flow path 517). In this embodiment, the first switching element module 11a and the second switching element module 11b are arranged on the back side of the cooler 50, and cooled by the cooling liquid flowing in the back side flow paths.

The direct current/direct current converter 21 is arranged on the front side of the cooler 50, and is cooled by the cooling liquid flowing through the front side flow paths (cooling flow path 511, cooling flow path 515 and cooling flow path 519). Specifically, the converter switching element 23a, the transformer 23b, the resonant reactor 23c, and the smoothing reactor 23d are arranged on the front side of the cooler 50, and are cooled by the cooling liquid flowing through the front side flow paths.

The boost converter 20 is arranged on the front side of the cooler 50, and is cooled by the cooling liquid flowing through the front side flow paths (cooling flow path 511, cooling flow path 515 and cooling flow path 519). Specifically, the boost switching element module 20a (see FIG. 1) and the reactor 20b are arranged on the front side of the cooler 50, and are cooled by the cooling liquid flowing in the front side flow paths. In this embodiment, the direct current/direct current converter 21 (see FIG. 1) is arranged on one direction side (Z1 direction side) of the cooler 50.

Also, the current sensor 30 is arranged on the front side of the cooler 50. Note that because the current sensor 30 is attached to the base 22 through the first boss 60 (see FIG. 2), the second boss 61 (see FIG. 2) and the third boss 62 (see FIG. 2), the current sensor is not cooled by the cooler 50.

### (Current Sensor)

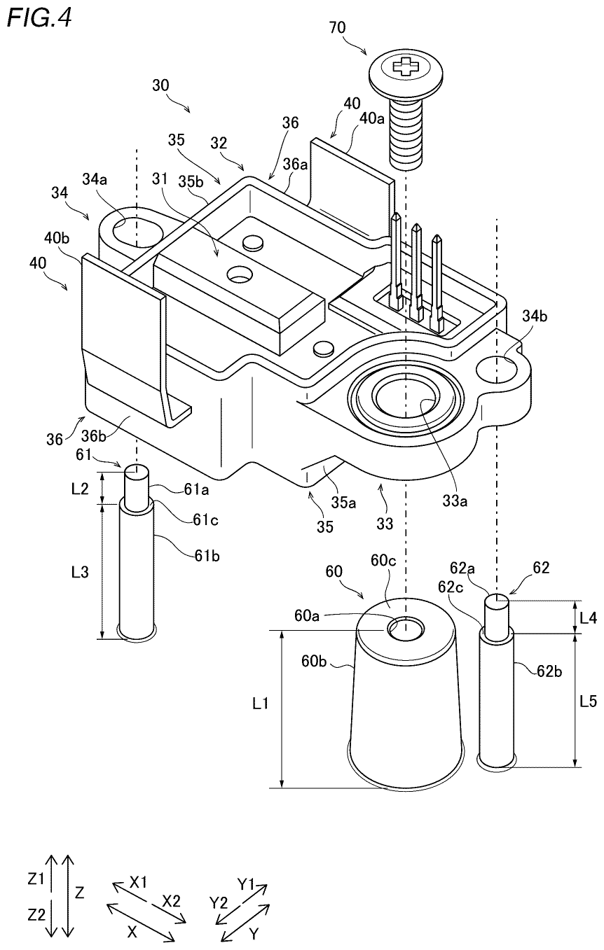

A configuration of the current sensor 30 according to this embodiment is now described with reference to FIGS. 4 to 6.

As shown in FIG. 4, the current sensor 30 includes a sensing part 31 and a housing 32. The base 22 (see FIG. 2) is omitted for ease of illustration in an exemplary arrangement shown in FIG. 4.

The sensing part 31 is configured to measure a current that flows through the boost converter 20 (see FIG. 2). The sensing part 31 can be an isolation ADC sensing type including a shunt resistor and an isolation amplifier, a cored current sensing type, and a coreless current sensing type configured to measure the current flowing through the boost converter 20.

Also, as shown in FIG. 4, the housing 32 has a single fastening through hole 33a through which a fastener 70 is inserted to fasten the current sensor to the base 22, and positioning through holes (first positioning through hole 34a and second positioning through hole 34b described later) for positioning the current sensor with respect to the base 22. The housing 32 is formed of an electrically insulating resin material. The fastener 70 is a screw, for example.

Also, as shown in FIG. 4, the housing 32 includes a first protruding part 33 and a second protruding part 34.

The first protruding part 33 is provided to the housing 32 to protrude from one side surface 35a of a pair of first side surfaces 35 facing each other. As shown in FIG. 4, the first protruding part 33 protrudes in the X2 direction from the side surface 35a on the X2 direction side of the pair of first side surfaces 35.

The second protruding part 34 is provided to the housing 32 to protrude from another side surface 35b of the pair of first side surfaces 35. As shown in FIG. 4, the second protruding part 34 protrudes in the X1 direction from the side surface 35b on the X1 direction side of the pair of first side surfaces 35.

In this embodiment, the fastening through hole 33a is provided in the first protruding part 33. The positioning through holes includes the first positioning through hole 34a provided in the second protruding part 34. Also, as shown in FIG. 4, the positioning through holes includes a second positioning through hole 34b provided in the first protruding part 33 to position the current sensor with respect to the base 22. The fastening through hole 33a is opened larger than the first positioning through hole 34a and the second positioning through hole 34b. Also, the first positioning through hole 34a is opened larger than the second positioning through hole 34b.

Also, as shown in FIG. 4, the current sensor 30 includes a pair of busbars 40 one of which is connected to the boost converter 20. The pair of busbars 40 are provided on a pair of second side surfaces 36, which are different from the pair of first side surfaces 35. The pair of busbars 40 extend in the Z1 direction.

One busbar 40a of the pair of busbars 40 protrudes from a side surface 36a on the Y1 direction side of the pair of second side surfaces 36. The busbar 40a is connected to a busbar provided in the reactor 20b (see FIG. 1).

Another busbar 40b of the pair of busbars 40 protrudes from a side surface 36b on the Y2 direction side of the pair of second side surfaces 36. The busbar 40b is connected to the boost switching element module 20a (see FIG. 1).

As shown in FIG. 4, the first boss 60 has an engagement hole 60a with which the fastener 70 engages, and a first pillar-like part 60b. The engagement hole 60a is provided in an end surface 60c of the first pillar-like part 60b on a side opposite to the base 22 (on the Z1 direction side). The first pillar-like part 60b has a cylindrical shape. The first pillar-like part 60b protrudes by a length L1 from the base 22 in the Z1 direction. Threaded grooves are formed in the engagement hole 60a.

Also, the second boss 61 includes a first protrusion 61a to be inserted into the first positioning through hole 34a, and a second pillar-like part 61b. The first protrusion 61a has a cylindrical shape. The first protrusion 61a is arranged on an end surface 61c of the second pillar-like part 61b on the side opposite to the base 22. A length L2 of the first protrusion 61a in the Z direction is not smaller than a thickness of the first positioning through hole 34a in the Z direction (thickness T2 of the second protruding part 34 in the Z direction (see FIG. 5)). The second pillar-like part 61b has a cylindrical shape. The second pillar-like part 61b protrudes by a length L3 from the base 22 in the Z1 direction.

Also, the third boss 62 includes a second protrusion 62a to be inserted into the second positioning through hole 34b, and a third pillar-like part 62b. The second protrusion 62a has a cylindrical shape. The second protrusion 62a is arranged on an end surface 62c of the third pillar-like part 62b on the side opposite to the base 22. A length L4 of the second protrusion 62a in the Z direction is not smaller than a thickness of the second positioning through hole 34b in the Z direction (thickness T1 of the first protruding part 33 in the Z direction (see FIG. 5)). The third pillar-like part 62b has a cylindrical shape. The third pillar-like part 62b protrudes by a length L5 from the base 22 in the Z1 direction.

In this embodiment, the length L1 of the first pillar-like part 60b, the length L3 of the second pillar-like part 61b, and the length L5 of the third pillar-like part 62b are equal to each other. Also, the length L1 of the first pillar-like part 60b, the length L3 of the second pillar-like part 61b, and the length L5 of the third pillar-like part 62b are greater than a thickness T3 of the housing 32 in the Z direction (see FIG. 5).

Accordingly, the current sensor 30 is fixed to the base 22 without the housing 32 being in contact with the base 22.

In this embodiment, as shown in FIG. 5, the housing 32 includes a first end surface 32a on the base 22 (see FIG. 2), and a second end surface 32b on a side opposite to the first end surface 32a. The first protruding part 33 and the second protruding part 34 are arranged on the pair of first side surfaces 35 on the first end surface 32a side to form stepped parts 37 between the second end surface 32b, and the first protruding part and the second protruding part. Specifically, the stepped parts 37 are formed so that the first protruding part 33 and the second protruding part 34 are arranged on the Z2 direction side with respect to the second end surface 32b.

Also, as shown in FIG. 5, the first protruding part 33 and the second protruding part 34 are arranged on both side surfaces of the pair of first side surfaces 35 at positions substantially equal to each other in the Z direction. Specifically, the first protruding part 33 and the second protruding part 34 are arranged on both side surfaces of the pair of first side surfaces 35 so that an end surface 33b of the first protruding part 33 on the Z2 side and an end surface 34c of the second protruding part 34 on the Z2 side are arranged at positions substantially equal to each other in the Z direction. Also, the first protruding part 33 and the second protruding part 34 are arranged on both side surfaces of the pair of first side surfaces 35 so that an end surface 33c of the first protruding part 33 on the Z1 side and an end surface 34d of the second protruding part 34 on the Z1 side are arranged at positions substantially equal to each other in the Z direction.

In this embodiment, as shown in FIG. 5, the housing 32 extends in the X2 direction, has a tapered shape whose thickness in the Z direction reduces in the X2 direction, and includes a connection part 33d connected to the first protruding part 33. Accordingly, it is possible to improve mechanical strength of the first protruding part 33. The connecting part 33d is integrally formed with the first protruding part 33.

In this embodiment, the housing 32 includes the first protruding part 33 with a center 33e of the first protruding part 33 in the Z direction being positioned on the Z1 side with respect to a center 35c between the first end surface 32a and the second end surface 32b as shown in FIG. 5. In this embodiment, the end surface 33b of the first protruding part 33 on the base 22 side is arranged on the second end surface 32b side with respect to the center 35c between the first end surface 32a and the second end surface 32b.

In this embodiment, the housing 32 includes the second protruding part 34 with a center 34e of the second protruding part 34 in the Z direction being positioned on the Z1 side with respect to the center 35c between the first end surface 32a and the second end surface 32b as shown in FIG. 5. In this embodiment, the end surface 34c of the second protruding part 34 on the base 22 side is arranged on the second end surface 32b side with respect to the center 35c between the first end surface 32a and the second end surface 32b.

In this embodiment, a thickness T1 of the first protruding part 33 in the Z direction is smaller than the thickness T3 of the housing 32 in the Z direction as shown in FIG. 5. Specifically, the thickness T1 of the first protruding part 33 in the Z direction is smaller than half the thickness T3 of the housing 32 in the Z direction.

In this embodiment, the thickness T2 of the second protruding part 34 in the Z direction is smaller than the thickness T3 of the housing 32 in the Z direction as shown in FIG. 5. Specifically, the thickness T2 of the second protruding part 34 in the Z direction is smaller than half the thickness T3 of the housing 32 in the Z direction.

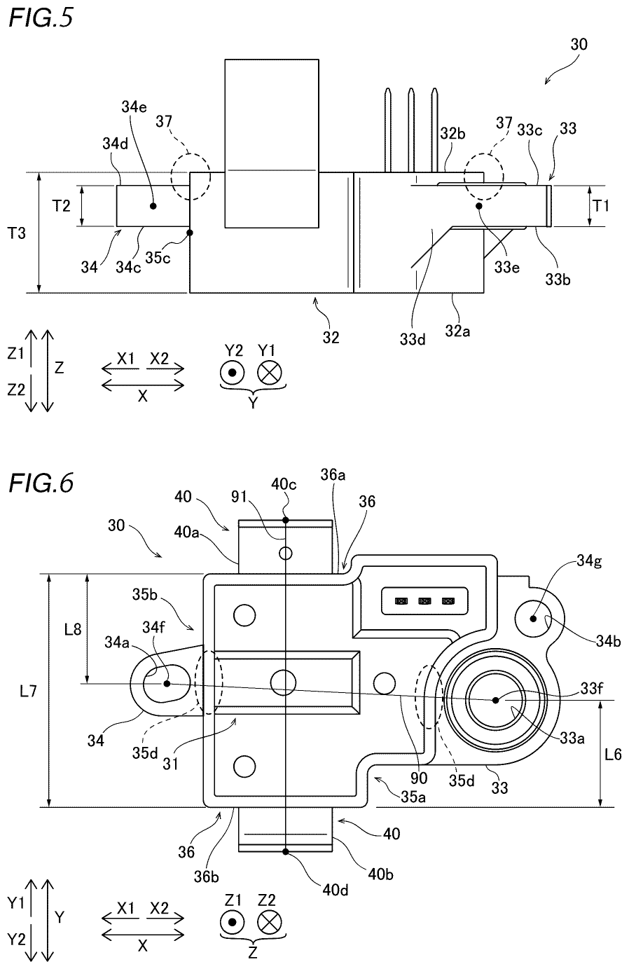

In this embodiment, as shown in FIG. 6, the first positioning through hole 34a has an elongated hole shape extending in the X direction in which the first protruding part 33 and the second protruding part 34 are aligned. As shown in FIG. 6, the second positioning through hole 34b has a round shape.

In this embodiment, as shown in FIG. 6, the first protruding part 33 has the fastening through hole 33a formed at a position aligned, in the X direction in which the first protruding part 33 and the second protruding part 34 are aligned, with one central part 35d of the pair of first side surfaces 35 in the Y direction intersecting the X direction. In addition, the second protruding part 34 has the first positioning through hole 34a formed at a position aligned, in the X direction, with another central part 35d of the pair of first side surfaces 35.

In other words, the first protruding part 33 has the fastening through hole 33a is positioned at a position corresponding to a length L6 in the Y direction between a center 33f of the fastening through hole 33a and the another side surface 36b of the second side surfaces 36, which is substantially half a length L7 of the housing 32 in the Y direction.

Also, the second protruding part 34 has the first positioning through hole 34a is positioned at a position corresponding to a length L8 in the Y direction between a center 34f of the first positioning through hole 34a and the one side surface 36a of the second side surfaces 36, which is substantially half the length L7 of the housing 32 in the Y direction.

That is, the central parts 35d of the pair of first side surfaces 35 in the Y direction refer not only to the central parts of the first side surfaces 35 in the Y direction but also to areas having a certain size including the central parts of the first side surfaces 35 in the Y direction.

As shown in FIG. 6, a part of the one side (X2 side) surface 35a of the pair of first side surfaces 35 protrudes in the X2 direction. Also, the another side (X1 side) surface 35b of the pair of first side surfaces 35 does not protrude toward the X1 direction side. That is, the side surface 35b is a flat surface extending in the Y direction.

In this embodiment, as shown in FIG. 6, the second positioning through hole 34b is arranged in a part of the first protruding parts 33 on the X2 side with respect to the fastening through hole 33a. In other words, the second positioning through hole 34b is formed in the first protruding part 33 so that a center 34g of the second positioning through hole 34b is positioned on the X2 direction side with respect to the center 33f of the fastening through hole 33a. Also, the second positioning through hole 34b is arranged in a part of the first protruding parts 33 on the Y1 side with respect to the fastening through hole 33a. In other words, the second positioning through hole 34b is formed in the first protruding part 33 so that a center 34g of the second positioning through hole 34b is positioned on the Y1 direction side with respect to the center 33f of the fastening through hole 33a.

In this embodiment, as shown in FIG. 6, the first protruding part 33 and the second protruding part 34, and the pair of busbars 40 are arranged so as to intersect each other. Here, an imaginary straight line 90 connecting the center 33f of the fastening through hole 33a to the center 34f of the first positioning through hole 34a, and an imaginary straight line 91 connecting a center 40c of the busbar 40a in the X direction to a center 40d of the busbar 40b in the X direction can be considered. In this embodiment, the first protruding part 33, the second protruding part 34, and the pair of busbars 40 are arranged in the housing 32 so that the imaginary straight line 90 and the imaginary straight line 91 are substantially orthogonal to each other. Here, a concept that the imaginary straight line 90 and the imaginary straight line 91 are substantially orthogonal to each other refers to a concept including not only that the imaginary straight line 90 and the imaginary straight line 91 intersect each other at 90 degrees but that they intersect each other at an angle greater (or smaller) a certain angle than 90 degrees.

Attachment of the current sensor 30 to the base 22 (see FIG. 2) is described with reference to FIG. 4. In the attachment of the current sensor 30 to the base 22, the second protrusion 62a is first inserted into the second positioning through hole 34b. Subsequently, the first protrusion 61a is inserted into the first positioning through hole 34a. As a result, the current sensor 30 can be positioned with respect to the base 22. Because the first positioning through hole 34a has an elongated shape, the position of the current sensor 30 can be adjusted in the X direction. Finally, the fastener 70 is inserted into the fastening through hole 33a for fastening. Consequently, the current sensor 30 is fixed to the base 22.

### Advantages of the Embodiments

In this embodiment, the following advantages are obtained.

In this embodiment, as described above, the power conversion apparatus 100 includes a boost converter 20 for boosting direct current power input from a direct current power supply 200; an inverter 10 for converting the direct current power boosted by the boost converter 20 into alternate current power and to supply the alternate current converted to a load 210; a direct current/direct current converter 21 for boosting the direct current power input from the direct current power supply 200; a current sensor 30 for measuring a current that flows through the boost converter 20; and a flat-plate-like base 22 on or above which the boost converter 20, the inverter 10, the direct current/direct current converter 21, and the current sensor 30 are arranged, wherein the current sensor 30 includes a sensing part 31 for measuring the current flowing through the boost converter 20, and a housing 32 having a single fastening through hole 33a through which a fastener 70 is inserted to fasten the current sensor to the base 22 and positioning through holes (first positioning through hole 34a and second positioning through hole 34b) for positioning the current sensor with respect to the base 22.

Accordingly, dissimilar to a configuration in which the housing 32 is fastened by a plurality of fasteners 70, because the housing 32 can be fastened to the base 22 by fastening a single fastener 70, it is possible to suppress increase of the number of parts. Also, because the housing 32 has the positioning through hole, it is possible to easily position the housing 32 by using the positioning through hole when the housing 32 is fixed to the base 22. Also, because the housing 32 can be fixed to the base 22 by fastening a single fastener 70, as compared with a case in which the housing 32 is fixed to the base 22 by fastening a plurality of fasteners 70, it is possible to reduce a burden in assembling work. Consequently, it is possible to suppress increase of the number of parts and reduce the number of work processes.

In this embodiment, as described above, the housing 32 includes a first protruding part 33 protruding from one side surface 35a of a pair of first side surfaces 35 facing each other, and a second protruding part 34 protruding from another side surface 35b of the pair of first side surfaces 35; the fastening through hole 33a is positioned in the first protruding part 33; and the positioning through holes include a first positioning through hole 34a provided in the second protruding part 34. Accordingly, because the first protruding part 33 and the second protruding part 34 protrude from different side surfaces 35a and 35b of the pair of first side surfaces 35, the fastening through hole 33a and the first positioning through hole 34a can be provided in different side surfaces 35a and 35b of the pair of first side surfaces 35. For this reason, as compared with a configuration in which the fastening through hole 33a and the first positioning through hole 34a are provided on a common side surface of the pair of first side surfaces 35, the fastening through hole 33a and the first positioning through hole 34a can be arranged at positions spaced further away from each other. Also, because the fastener 70 inserted into the fastening through hole 33a also facilitates to position the housing 32, as compared with the configuration in which the fastening through hole 33a and the first positioning through hole 34a are provided on the common side surface of the pair of first side surfaces 35, the housing 32 can be positioned by using two positions spaced further away from each other. For this reason, it is possible to accurately position the housing 32 when the housing 32 is fixed by the fastener 70. Consequently, as compared with the configuration in which the fastening through hole 33a and the first positioning through hole 34a are provided on the common side surface of the pair of first side surfaces 35, it is possible to improve positioning accuracy of the current sensor 30 when fixing the current sensor 30 to the base 22.

In this embodiment, as described above, the positioning through holes further includes a second positioning through hole 34b provided in the first protruding part 33 to position the current sensor with respect to the base 22. Accordingly, because the current sensor 30 can be positioned by using two positioning through holes, which are the first positioning through hole 34a and the second positioning through hole 34b, as compared with a case in which only the positioning through hole is provided, it is possible to easily and reliably position the current sensor 30.

In this embodiment, as described above, the first positioning through hole 34a has an elongated hole shape extending in an X direction in which the first protruding part 33 and the second protruding part 34 are aligned; and the second positioning through hole 34b has a round shape. Accordingly, because the first positioning through hole 34a has an elongated hole shape extending in the X direction, it is possible to absorb manufacturing errors of the housing 32 and the base 22 in the X direction. In addition, because the first positioning through hole 34a has an elongated hole shape extending in the X direction, it is possible to position the housing 32 with respect to the base 22 in a Y direction intersecting the X direction while absorbing manufacturing errors of the housing 32 and the base 22 in the X direction. Consequently, the current sensor 30 can be easily positioned by positioning the housing 32 with respect to the second positioning through hole 34b, which has a round shape, even if the housing 32 and the base 22 have manufacturing errors in the X direction.

In this embodiment, as described above, the housing 32 have a first end surface 32a on the base 22 side, and a second end surface 32b opposite to the first end surface 32a; and the first protruding part 33 and the second protruding part 34 are arranged on the pair of the first side surfaces 35 on the first end surface 32a side to form stepped parts 37 between the second end surface 32b, and the first protruding part and the second protruding part. Here, for example, in a case in which the current sensor 30 is fixed to the base 22 without being in contact with the base, the housing 32 is fixed to a first boss 60 that is formed on the base 22 and has an engagement hole 60a with which the fastener 70 engages. Also, a second boss 61 that has a first protrusion 61a to be inserted into the first positioning through hole 34a is formed on the base 22 to position the housing 32 when positioning the housing 32. If a height of the first boss 60 that has the engagement hole 60a (a length L1 of the first pillar-like part 60b) is large, and a height of the second boss 61 that has the first protrusion 61a to be inserted into the first positioning through hole 34a (a length L3 of the second pillar-like part 61b) is large, a material amount of the base 22 increases. To address this, according to this configuration, it is possible to arrange the fastening through hole 33a and the positioning through hole closer to the base 22 as compared with a configuration in which the fastening through hole 33a and the positioning through hole are arranged coplanar with the second end surface 32b. For this reason, it is possible to reduce the height of the first boss 60 that has the engagement hole 60a for the fastener 70 for fastening the current sensor to the base 22 (the length L1 of the first pillar-like part 60b), the height of the second boss 61 that has the first protrusion 61a to be inserted into the positioning through hole and to position the current sensor 30 (the length L3 of the second pillar-like part 61b), and a height of a third boss 62 that has a second protrusion 62a to be inserted into a positioning through hole and to position the current sensor 30 (a length L5 of a third pillar-like part 62b). Consequently, it is possible to reduce a material amount of the base 22 as compared with the configuration in which the fastening through hole 33a and the positioning through hole are arranged coplanar with the second end surface 32b.

In this embodiment, as described above, an end surface 33b of the first protruding part 33 on the base 22 side, and an end surface 34c of the second protruding part 34 on the base 22 side are located on the second end surface 32b side with respect to the center 35c between the first end surface 32a and the second end surface 32b. Here, in a case in which the first protruding part 33 and the second protruding part 34 are arranged closer to the first end surface 32a, the first protruding part 33 and the second protruding part 34 are located at far places from a viewpoint of a worker when the worker attaches the current sensor 30 to the base 22. For this reason, as compared with a case in which the first protruding part 33 and the second protruding part 34 are located at places closer from a viewpoint of the worker, the worker cannot easily see position of the first positioning through hole 34a when inserting the first protrusion 61a for positioning into the first positioning through hole 34a formed in the second protruding part 34. In addition, the worker cannot easily see position of the fastening through hole 33a when inserting the fastener 70 into the fastening through hole 33a formed in the first protruding part 33. Contrary to this, according to this configuration, the positions of the first protruding part 33 and the second protruding part 34 can be closer to the second end surface 32b side while stepped parts 37 can be formed between the first protruding part and the second protruding part, and the second end surface 32b. Accordingly, the fastening through hole 33a and the first positioning through hole 34a can be located closer to the second end surface 32b. As a result, the worker can easily see position of the first positioning through hole 34a when positioning the current sensor 30. In addition, the worker can easily see position of the fastening through hole 33a when fixing the current sensor 30 to the base 22. Consequently, the worker can easily position and fasten the current sensor 30 while a material amount of the base 22 is reduced.

In this embodiment, as described above, the first protruding part 33 has the fastening through hole 33a formed at a position aligned, in an X direction in which the first protruding part 33 and the second protruding part 34 are aligned, with one central part 35d of the pair of first side surfaces 35 in a Y direction intersecting the X direction; and the second protruding part 34 has the first positioning through hole 34a formed at a position aligned, in the X direction, with another central part 35d of the pair of first side surfaces 35. Accordingly, a fastening force can be applied to a central part of the housing 32 in the Y direction when the current sensor 30 is fixed to the base 22. As a result, because the fastening force can be evenly applied to one end side and another end side of the housing 32 in the Y direction, it is possible to stably fix the current sensor 30 to the base 22 as compared with a configuration in which the fastening through hole 33a is arranged in a part on one of the end sides in the Y direction.

In this embodiment, as described above, the current sensor 30 further includes a pair of busbars 40 one of which is connected to the boost converter 20; and the pair of busbars 40 is provided on a pair of second side surfaces 36, which are different from the pair of first side surfaces 35. Accordingly, because the pair of busbars 40 is provided on the pair of second side surfaces 36, which are different from the pair of first side surfaces 35, the pair of busbars 40 can be prevented from interfering with positioning and fastening work when the current sensor 30 is positioned and fastened as compared to a configuration in which the pair of busbars 40 is provided on the pair of first side surfaces 35. Consequently, it is possible to improve workability of positioning and fastening the current sensor 30.

### Modified Embodiments

Note that the embodiment disclosed this time must be considered as illustrative in all points and not restrictive. The scope of the present invention is not shown by the above description of the embodiments but by the scope of claims for patent, and all modifications (modified examples) within the meaning and scope equivalent to the scope of claims for patent are further included.

While the example in which a housing 32 includes a first protruding part 33 and a second protruding part 34, a fastening through hole 33a is positioned in the first protruding part 33, and a first positioning through hole 34a is provided in the second protruding part 34 has been shown in the aforementioned embodiment. For example, alternatively, the housing can include no first and second protruding parts 33 and 34. In this case, the fastening and the first positioning through hole can be arranged at positions of the housing 32 opposite to each other.

While the example in which the housing 32 includes the first protruding part 33 and the second protruding part 34, the fastening through hole 33a is positioned in the first protruding part 33, and the first positioning through hole 34a is provided in the second protruding part 34 has been shown in the aforementioned embodiment, the present invention is not limited to this. For example, the fastening through hole and the first positioning through hole are not necessarily arranged at positions opposite to each other. The fastening through hole and the first positioning through hole can be provided in one common surface of a pair of first side surfaces 35, or one of the fastening through hole and the first positioning through hole can be provided in one of the first side surfaces 35 while another can be provided in one of second side surfaces 36.

While the example in which the positioning through holes include a second positioning through hole 34b has been shown in the aforementioned embodiment, the present invention is not limited to this. For example, alternatively, the positioning through holes can include no second positioning through hole 34b. However, in a case in which the positioning through hole does not include the second positioning through hole 34b, workability in positioning work of the current sensor 30 will be reduced. For this reason, the positioning through holes include the second positioning through hole 34b.

While the example in which the positioning through holes include two positioning through holes, which are the first positioning through hole 34a and the second positioning through hole 34b, has been shown in the aforementioned embodiment, the present invention is not limited to this. For example, alternatively, the positioning through holes can include three or more positioning through holes.

While the example in which the first positioning through hole 34a has an elongated hole shape extending in an X direction, and the second positioning through hole 34b has a round shape has been shown in the aforementioned embodiment, the present invention is not limited to this. For example, alternatively, the first positioning through hole can have a round shape, and the second positioning through hole can have an elongated shape extending in the X direction.

While the example in which the first positioning through hole 34a has an elongated hole shape, and the second positioning through hole 34b has a round shape has been shown in the aforementioned embodiment, the present invention is not limited to this. For example, alternatively, both the first and second positioning through holes can have a round shape. However, in a case in which both the first and second positioning through holes have a round shape, it will be difficult to absorb manufacturing errors of the housing 32 and the base 22 in the X direction. For this reason, the first or second positioning through hole has an elongated shape.

While the example in which the first protruding part 33 and the second protruding part 34 are arranged on the first end surface 32a side to form stepped parts 37 between a second end surface 32b, and the first protruding part and the second protruding part has been shown in the aforementioned embodiment, the present invention is not limited to this. For example, alternatively, the first protruding part 33 and the second protruding part 34 can be arranged on the pair of first side surfaces 35 so as not to form the stepped parts 37 between the second end surface 32b, and the first protruding part and the second protruding part. However, in a case in which the first protruding part 33 and the second protruding part 34 are arranged on the pair of first side surfaces 35 so as not to form the stepped parts 37 between the second end surface 32b, and the first protruding part and the second protruding part, it is necessary to increase the heights of the first boss 60, the second boss 61, and the third boss 62, and as a result an amount of a material forming the base 22 increases. For this reason, the first protruding part 33 and the second protruding part 34 are arranged on the first end surface 32a side to form the stepped parts 37 between the second end surface 32b, and the first protruding part and the second protruding part

While the example in which an end surface 33b of the first protruding part 33 on the base 22 side, and an end surface 34c of the second protruding part 34 on the base 22 side are located on the second end surface 32b side with respect to the center 35c between the first end surface 32a and the second end surface 32b has been shown in the aforementioned embodiment, the present invention is not limited to this. For example, alternatively, the end surface 33b of the first protruding part 33 on the base 22 side, and the end surface 34c of the second protruding part 34 on the base 22 side can be located on the first end surface 32a side with respect to the center 35c between the first end surface 32a and the second end surface 32b. However, in a case in which the end surface 33b of the first protruding part 33 on the base 22 side, and the end surface 34c of the second protruding part 34 on the base 22 side are located on the first end surface 32a side with respect to the center 35c between the first end surface 32a and the second end surface 32b, workability in positioning and fastening work of the current sensor 30 will be reduced. For this reason, the end surface 33b of the first protruding part 33 on the base 22 side, and the end surface 34c of the second protruding part 34 on the base 22 side are located on the second end surface 32b side with respect to the center 35c between the first end surface 32a and the second end surface 32b.

While the example in which the fastening through hole 33a and the first positioning through hole 34a are formed at positions aligned in the X direction with the central parts 35d of the pair of first side surfaces 35 in the first protruding part 33 and the second protruding part 34 has been shown in the aforementioned embodiment, the present invention is not limited to this. For example, in the present invention, alternatively, the fastening through hole 33a and the first positioning through hole 34a can be formed at positions other than the positions aligned in the X direction with the central parts of the pair of first side surfaces 35 in the first protruding part 33 and the second protruding part 34. However, in a case in which the fastening through hole 33a and the first positioning through hole 34a are formed at positions other than the positions aligned in the X direction with the central parts 35d of the pair of first side surfaces 35 in the first protruding part 33 and the second protruding part 34, it will be difficult to evenly apply a fastening force to on one end side and another end side in the Y direction by using the fastener 70, and as a result it will be difficult to stably fix the current sensor 30 to the base 22. For this reason, the fastening through hole 33a and the first positioning through hole 34a are formed at positions aligned in the X direction with the central parts 35d of the pair of first side surfaces 35 in the first protruding part 33 and the second protruding part 34.

While the example in which a pair of busbars 40 is arranged on the pair of second side surfaces 36 has been shown in the aforementioned embodiment, the present invention is not limited to this. For example, in the present invention, alternatively, the pair of busbars can be arranged on the pair of first side surfaces 35. However, in a case in which the configuration in which the pair of busbars can be arranged on the pair of first side surfaces 35, the pair of busbars will interfere with positioning and fastening work when the current sensor 30 is positioned and fastened. For this reason, the pair of busbars 40 is arranged on the pair of second side surfaces 36

While the example in which the current sensor 30 includes the pair of busbars 40 one of which is connected to the boost converter 20 has been shown in the aforementioned embodiment, the present invention is not limited to this. For example, alternatively, the current sensor can include no busbars 40. In this case, the current sensor can include wires connected to the boost converter 20 so as to flow a current.

While the example in which the fastening through hole 33a is opened larger than the first positioning through hole 34a and the second positioning through hole 34b has been shown in the aforementioned embodiment, the present invention is not limited to this. For example, alternatively, the fastening through hole can be opened the same size as the first positioning through hole 34a and the second positioning through hole 34b, or be opened smaller than the first positioning through hole 34a and the second positioning through hole 34b. The fastening through hole 33a can be opened in any size as long as the fastener 70 can be inserted into the fastening through hole.

While the example in which the first positioning through hole 34a is opened larger than the second positioning through hole 34b has been shown in the aforementioned embodiment, the present invention is not limited to this. For example, alternatively, the first positioning through hole 34a can be opened the same size as the second positioning through hole 34b, or be opened smaller than the second positioning through hole 34b. The first positioning through hole 34a and the second positioning through hole 34b can be opened in any sizes as long as the current sensor 30 can be positioned.

While the example in which the power conversion apparatus 100 includes a cooler 50 arranged between an inverter 10 and a direct current/direct current converter 21 to cool the inverter 10 and the direct current/direct current converter 21 has been shown in the aforementioned embodiment, the present invention is not limited to this. For example, alternatively, the power conversion apparatus can include no cooler 50. However, in a case in which the power conversion apparatus does not include the cooler 50, the inverter 10 and the direct current/direct current converter 21 are not cooled, and as a result power conversion efficiency decreases. For this reason, the power conversion apparatus 100 includes the cooler 50.

While the example in which the direct current/direct current converter 21 is arranged on the Z1 direction side, and the inverter 10 is arranged on the Z2 direction side has been shown in the aforementioned embodiment, the present invention is not limited to this. For example, alternatively, the direct current/direct current converter 21 can be arranged on the Z2 direction side, and the inverter 10 can be arranged on the Z1 direction side.

What is claimed is:

1. A power conversion apparatus comprising:
a boost converter for boosting direct current power input from a direct current power supply;
an inverter for converting the direct current power boosted by the boost converter into alternate current power to supply the alternate current converted to a load;
a direct current/direct current converter for boosting the direct current power input from the direct current power supply;
a current sensor for measuring a current that flows through the boost converter; and
a flat-plate-shape base to which the boost converter, the inverter, the direct current/direct current converter, and the current sensor are arranged, wherein
the current sensor includes a sensing part for measuring the current flowing through the boost converter, and a housing having a single fastening through hole through which a fastener is inserted to fasten the current sensor to the base and a positioning through hole for positioning the current sensor with respect to the base.

2. The power conversion apparatus according to claim 1, wherein
the housing includes a first protruding part protruding from one side surface of a pair of first side surfaces facing each other, and a second protruding part protruding from another side surface of the pair of first side surfaces;
the fastening through hole is provided in the first protruding part; and
the positioning through hole includes a first positioning through hole provided in the second protruding part.

3. The power conversion apparatus according to claim 2, wherein the positioning through hole further includes a second positioning through hole provided in the first protruding part for positioning the current sensor with respect to the base.

4. The power conversion apparatus according to claim 3, wherein
the first positioning through hole has an elongated hole shape extending in a first direction in which the first protruding part and the second protruding part are aligned; and
the second positioning through hole has a round shape.

5. The power conversion apparatus according to claim 2, wherein
the housing have a first end surface on the base side, and a second end surface opposite to the first end surface; and
the first protruding part and the second protruding part are arranged on the pair of the first side surfaces on the first end surface side to form stepped parts between the second end surface, and the first protruding part and the second protruding part.

6. The power conversion apparatus according to claim 5, wherein an end surface of the first protruding part on the base side, and an end surface of the second protruding part on the base side are located on the second end surface side with respect to a center between the first end surface and the second end surface.

7. The power conversion apparatus according to claim 2, wherein
the first protruding part has the fastening through hole formed at a position aligned, in a first direction in which the first protruding part and the second protruding part are aligned, with a central part of the pair of first side surfaces in a second direction intersecting the first direction; and
the second protruding part has the first positioning through hole formed at a position aligned, in the first direction, with a central part of the pair of first side surfaces.

8. The power conversion apparatus according to claim 2, wherein
the current sensor further includes a pair of busbars one of which is connected to the boost converter; and
the pair of busbars is provided on a pair of second side surfaces, which is different from the pair of first side surfaces.
